(19) United States
(12) Patent Application Publication
(10) Pub. No.: US 2023/0139556 A1
(43) Pub. Date: May 4, 2023

(54) THERMOELECTRIC CONVERSION MODULE

(71) Applicant: LINTEC CORPORATION, Tokyo (JP)

(72) Inventors: Yuta SEKI, Kawasaki-shi, Kanagawa (JP); Tsuyoshi MUTO, Saitama-shi, Saitama (JP)

(73) Assignee: LINTEC CORPORATION, Tokyo (JP)

(21) Appl. No.: 17/915,549

(22) PCT Filed: Mar. 19, 2021
(86) PCT No.: PCT/JP2021/011334

§ 371 Date: Sep. 29, 2022

(30) Foreign Application Priority Data
Mar. 30, 2020 (JP) 2020-061387

(51) Int. Cl. H10N 10/17

(52) U.S. Cl. CPC H10N 10/17; H10N 10/13

(57) ABSTRACT

Provided is a thermoelectric conversion module in which heat dissipation is further improved with a simple structure. The thermoelectric conversion module is a thermoelectric conversion module including a first electrode, a P-type thermoelectric element layer and an N-type thermoelectric element layer, and a second electrode disposed opposite the first electrode. The thermoelectric conversion module includes a plurality of PN-junction pairs in which the P-type thermoelectric element layer and the N-type thermoelectric element layer are PN-joined through the first electrode or the second electrode, the plurality of PN-junction pairs being electrically connected in series alternately by the first electrode and the second electrode. An area of the second electrode is larger than an area of the first electrode.

### TECHNICAL FIELD

The present invention relates to a thermoelectric conversion module.

### BACKGROUND ART

There has been a thermoelectric conversion module that inter-converts thermal energy and electrical energy using a thermoelectric conversion material having a thermoelectric effect such as a Seebeck effect or a Peltier effect.

As such a thermoelectric conversion module, a configuration of a so-called π-type thermoelectric conversion element is known. The π-type is formed, for example, by providing a pair of electrodes spaced apart from each other on a substrate and providing a lower surface of a P-type thermoelectric element on one electrode and a lower surface of an N-type thermoelectric element on the other electrode, with the thermoelectric elements being similarly spaced apart from each other, and joining opposite-side upper surfaces of the P-type thermoelectric element and the N-type thermoelectric element to electrodes of an opposing substrate (hereinafter, sometimes referred to as “PN-joining”). In general, a plurality of pairs of P-type thermoelectric elements and N-type thermoelectric elements, which are PN-joined, are used from the perspective of thermoelectric performance, and are configured to achieve electrical series connection and thermal parallel connection.

In electronic devices such as computers, mirrorless cameras, and mobile terminals including smartphones, electronic elements typified by semiconductor elements such as CPUs (Central Processing Units), CMOSs (Complementary Metal Oxide Semiconductors), and light emitting diodes that operate and control the electronic devices have been commonly mounted on a substrate at high density. As the semiconductor elements have become smaller and had higher performance due to miniaturization, the semiconductor elements themselves have become heat generating elements that are hot and emit a large amount of heat. In such a situation, there is a demand for cooling devices that further efficiently absorb and dissipate heat generated from the semiconductor elements and the like.

One of the methods dealing with such a demand includes, for example, electron cooling using the thermoelectric conversion module.

Patent Document 1 discloses a heat dissipation structure that includes: a Peltier element used as a cooling element in which a heat absorption surface is joined to a surface of an electronic element on a substrate; and further a pedestal which is connected to a side of the heat dissipation surface of the cooling element to dissipate heat from the electronic element, the pedestal including: a metal plate material which has a surface having an area larger than an area of the heat dissipation surface of the cooling element and equal to or smaller than a surface area of the substrate; and a thermal conductive sheet which has a surface having an area larger than the area of the heat dissipation surface of the cooling element and equal to or smaller than the surface area of the substrate, wherein one surface is joined to the plate material and the other surface is joined to the heat dissipation surface of the cooling element.

### CITATION LIST

### Patent Literature

Patent Document 1: WO 2013/153667

### SUMMARY OF INVENTION

### Technical Problem

However, in Patent Document 1, in the structure that dissipates heat from the electronic element on the substrate, the pedestal in which the metal plate material and the thermal conductive sheet are joined is further thermally connected to the heat dissipation surface of the Peltier element used as the cooling element. Moreover, for example, a pair of thermal conductive metal plates sandwiching a graphite sheet from both sides is used as the thermal conductive sheet, and thus the configuration becomes complicated, which may be a problem from the perspectives of addition of manufacturing process, complexity of mounting, material cost increase, and the like.

In view of the above, an object of the present invention is to provide a thermoelectric conversion module in which heat dissipation is further improved with a simple structure.

### Solution to Problem

As a result of diligent studies to solve the above problems, the present inventors have found that, when an area of a second electrode for use in formation of a PN-junction pair of a P-type thermoelectric element and an N-type thermoelectric element constituting a thermoelectric conversion module is made larger than an area of a first electrode for use in formation of an opposing PN-junction pair, heat dissipation from a surface of the second electrode is further improved, and have completed the present invention.

That is, the present invention provides the following (1) to (6).

(1) A thermoelectric conversion module including a first electrode, a P-type thermoelectric element layer and an N-type thermoelectric element layer, and a second electrode disposed opposite the first electrode, the thermoelectric conversion module including a plurality of PN-junction pairs in which the P-type thermoelectric element layer and the N-type thermoelectric element layer are PN-joined through the first electrode or the second electrode, the plurality of PN-junction pairs being electrically connected in series alternately by the first electrode and the second electrode,

wherein an area of the second electrode is larger than an area of the first electrode.

(2) The thermoelectric conversion module according to (1), wherein a ratio R of the area of the second electrode to the area of the first electrode is 1.20 or greater.

(3) The thermoelectric conversion module according to (1) or (2), further including a first substrate and/or a second substrate.

(4) The thermoelectric conversion module according to any one of (1) to (3), wherein an extending portion of the second electrode is thermally connected to a member including a high thermal conductive material.

(5) The thermoelectric conversion module according to any one of (1) to (4), wherein the second substrate has a through-hole, and the second electrode is formed on both sides of the second substrate through the through-hole; and an other electrode surface side of the second electrode, which is opposite to one electrode surface side on the P-type thermoelectric element layer and N-type thermoelectric element layer side, extends on the second substrate on the opposite side of the second substrate from the P-type thermoelectric element layer and N-type thermoelectric element layer side and is disposed as a continuous layer.

(6) The thermoelectric conversion module according to any one of (1) to (5), wherein the thermoelectric conversion module is disposed inside the through-hole of the second substrate, and the second electrode of the thermoelectric conversion module extends on the second substrate through the through-hole, and is disposed as a continuous layer.

### Advantageous Effects of Invention

The present invention can provide a thermoelectric conversion module in which heat dissipation is further improved with a simple structure.

### BRIEF DESCRIPTION OF DRAWINGS

FIG. 1 is a transparent perspective view illustrating a configuration of a thermoelectric conversion module according to a first embodiment of the present invention.

FIG. 2 is a perspective view illustrating an example of a configuration of a known thermoelectric conversion module.

FIG. 3 is a transparent perspective view illustrating a configuration of a thermoelectric conversion module according to a second embodiment of the present invention.

FIG. 4 is a cross-sectional view illustrating a configuration of a thermoelectric conversion module according to a third embodiment of the present invention.

FIG. 5 is a cross-sectional view illustrating a configuration of a thermoelectric conversion module according to a fourth embodiment of the present invention.

### DESCRIPTION OF EMBODIMENTS

### Thermoelectric Conversion Module

The thermoelectric conversion module of the present invention includes a first electrode, a P-type thermoelectric element layer and an N-type thermoelectric element layer, and a second electrode disposed opposite the first electrode. The thermoelectric conversion module includes a plurality of PN-junction pairs in which the P-type thermoelectric element layer and the N-type thermoelectric element layer are PN-joined through the first electrode or the second electrode, the plurality of PN-junction pairs being electrically connected in series alternately by the first electrode and the second electrode. An area of the second electrode is larger than an area of the first electrode.

In the thermoelectric conversion module of the present invention, the area of the second electrode constituting the thermoelectric conversion module is larger than the area of the first electrode, and thus, for example, when an object to be cooled is disposed such that the first electrode side is a heat absorption surface, and thereafter the thermoelectric conversion module is energized, heat generated from the object to be cooled can be efficiently dissipated from the second electrode.

Note that the thermoelectric conversion element is typically reversed in positional relationship between a heat absorption side and a heat dissipation side, depending on a direction of the energization. In addition, when the heat absorption side and the heat dissipation side are switched, output polarity is switched. Because of this, the present invention is not limited in terms of which electrode side is the heat absorption side or the heat dissipation side. In the present specification, for convenience, the second electrode side is referred to as heat dissipation side, and the first electrode side is referred to as heat absorption side.

Hereinafter, the present invention will be specifically described by way of embodiments with reference to drawings.

### First Embodiment

The configuration of the thermoelectric conversion module of the present invention preferably further includes a first substrate and/or a second substrate. For example, when the second substrate is provided, a distribution of heat dissipation generated from the second electrode is made uniform, and the heat dissipation is further improved.

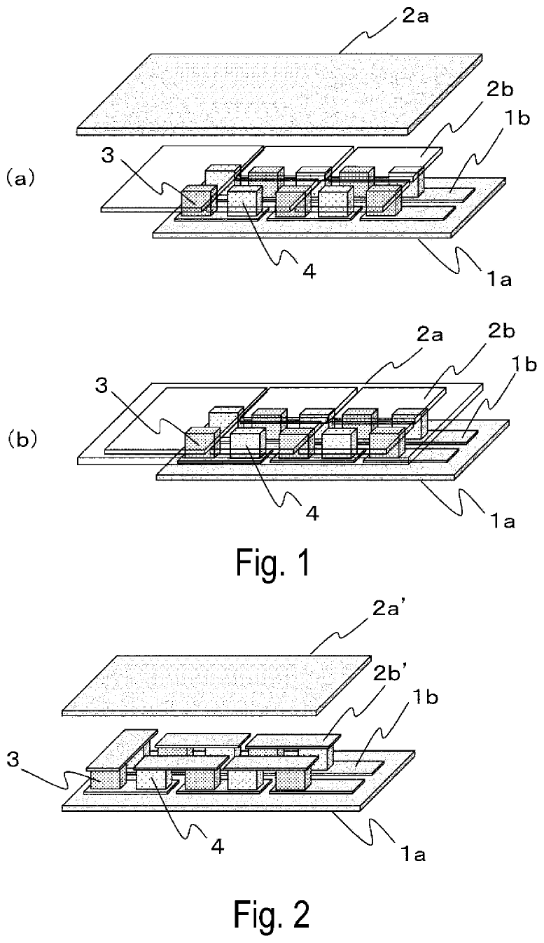

FIG. 1 is a transparent perspective view (a configuration part is visualized) illustrating a configuration of a thermoelectric conversion module according to a first embodiment of the present invention, in which (a) is a transparent perspective view illustrating an aspect of arrangement of the second electrode, and (b) is a transparent perspective view illustrating an overall configuration of the thermoelectric conversion module.

The thermoelectric conversion module according to an embodiment of the present invention is configured as a so-called π-type thermoelectric conversion element, and includes, for example: a first substrate 1a having a first electrode 1b; a P-type thermoelectric element layer 3 and an N-type thermoelectric element layer 4; and a second electrode 2b disposed opposite the first electrode 1b, and further includes a second substrate 2a on the second electrode 2b.

As for the areas of the first electrode 1b and the second electrode 2b opposed to each other, the area of the second electrode 2b is larger than the area of the first electrode 1b.

In addition, in FIG. 1, a plurality of PN-junction pairs in which the P-type thermoelectric element layer 3 and the N-type thermoelectric element layer 4 are PN-joined through the first electrode 1b or the second electrode 2b are electrically connected in series or thermally connected in parallel alternately by the first electrode and the second electrode. The PN-junction pair composed of the P-type thermoelectric element layer 3 and the N-type thermoelectric element layer 4 is not particularly limited. A plurality of PN-junction pairs are usually adopted, and can be appropriately adjusted and used.

FIG. 2 is a perspective view illustrating an example of a configuration of a known thermoelectric conversion module.

A known thermoelectric conversion module is configured as a so-called π-type thermoelectric conversion element, and includes, for example: a first substrate 1a having a first electrode 1b; a P-type thermoelectric element layer 3 and an N-type thermoelectric element layer 4; and a second electrode 2b′ disposed opposite the first electrode 1b, and further includes a second substrate 2a′ on the second electrode 2b′.

In terms of the areas of the first electrode 1b the and the second electrode 2b′ opposed to each other, electrodes having approximately the same area are usually used.

In the thermoelectric conversion module of an embodiment of the present invention, a surface of the first substrate 1a on a side opposite to the first electrode 1b side can be a heat absorption surface, and the other surface thereof, which is a surface on a side opposite to the second electrode 2b or the second electrode 2b side of the second substrate 2a, can be a heat dissipation surface. For example, the object to be cooled is disposed on the heat absorption surface, and is joined.

The object to be cooled is not particularly limited, and includes electronic elements. Among them, an electronic element is preferably cooled from the perspective of efficiently cooling in a short period of time. The electronic element includes heat-generating electronic components such as CPUs, CMOSs, light emitting diodes, semiconductor lasers, and capacitors, and typically includes those disposed on a mounting portion of a circuit board.

The number of objects to be cooled is not particularly limited, and may be two or greater.

Examples of a method for joining the object to be cooled include adhesion with an adhesive, solder, and known methods.

In an embodiment of the present invention, a ratio R of the area of the second electrode to the area of the first electrode (hereinafter, the ratio R of the area of the second electrode to the area of the first electrode is referred to as “ratio R”) depends on the electrode materials used, but, when the same electrode material is used, is preferably 1.2 or greater, and is more preferably 1.5≤R≤100.0, even more preferably 2.0≤R≤50.0, more preferably 4.0≤R≤25.0, and particularly preferably 6.0≤R≤16.0. When the ratio R is within this range, heat dissipation is improved, and the object to be cooled can be allowed to arrive at a predetermined temperature in a shorter period of time, and maintained at the temperature.

The arrangement of the thermoelectric element layers such as the P-type thermoelectric element layer 3 and the N-type thermoelectric element layer 4 constituting the thermoelectric conversion module is not particularly limited. However, the thermoelectric element layers are preferably disposed in two rows and a plurality of columns, as illustrated in FIG. 1, from the perspective of increasing the area of the second electrode 2b. However, when the thermoelectric element layers are disposed in a plurality of rows and a plurality of columns, for example, the periphery of the plurality of thermoelectric element layers may be surrounded by adjacent other thermoelectric element layers. For example, in an arrangement of three rows and a plurality of columns (not illustrated), the periphery of the thermoelectric element layers disposed in the central second row may be wholly surrounded by adjacent thermoelectric element layers, and may be physically close to each other. In such a case, it is preferable to adjust the area of the second electrode 2b to be larger as appropriate, in a range where electrical connection and thermal connection to the thermoelectric conversion module of the present invention are not impaired, and in a range where the ratio R is satisfied.

A total area of joint surfaces of the P-type thermoelectric element layer 3 and the N-type thermoelectric element layer 4 to the electrode is not particularly limited, but is usually smaller than the area of the electrode. Additionally, the thermoelectric element layers having the same size are preferably used, from the perspective of uniformity of performance balance associated with the PN-junction pair and ease of manufacturing.

According to the first embodiment, for example, when the object to be cooled is disposed on a heat absorption surface which is the first substrate 1a side having the first electrode 1b, heat from the object to be cooled is absorbed from the heat absorption surface which is the first substrate 1a side, and dissipated from the second substrate 2a side having the second electrode 2b. Since the area of the second electrode 2b is larger than the area of the first electrode 1b, the heat dissipation is efficiently and sufficiently performed from the second substrate 2a. The thermoelectric conversion module having such a configuration enables efficient dissipation of the heat generated from the object to be cooled.

### Second Embodiment

In the configuration of the thermoelectric conversion module of the present invention, an extending portion of the second electrode is preferably thermally connected to a member including a high thermal conductive material.

Here, the extending portion means a region where the second electrode extends in a horizontal direction.

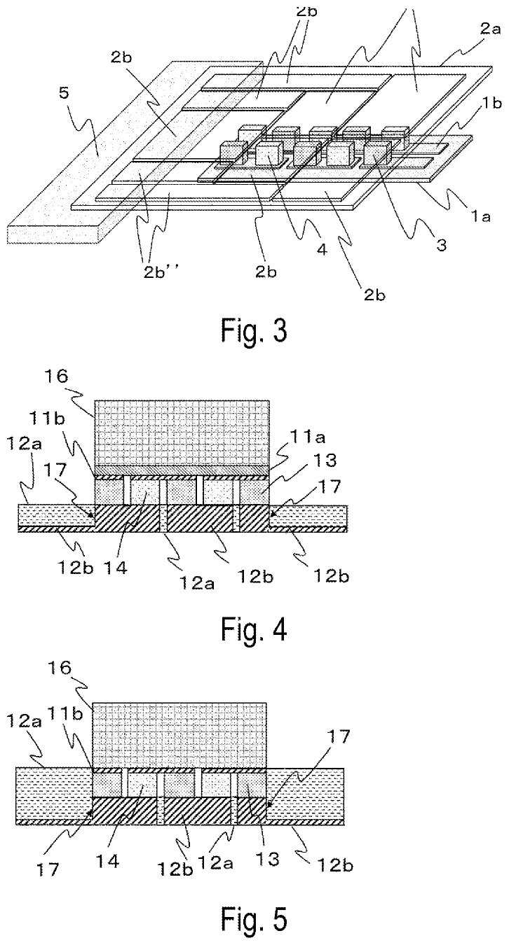

FIG. 3 is a transparent perspective view illustrating a configuration of a thermoelectric conversion module according to a second embodiment of the present invention (a configuration part is visualized).

Similarly to the thermoelectric conversion module of the first embodiment, the thermoelectric conversion module according to the second embodiment includes: a first substrate 1a having a first electrode 1b; a P-type thermoelectric element layer 3 and an N-type thermoelectric element layer 4; and a second electrode 2b disposed opposite the first electrode 1b, and further includes a second substrate 2a on the second electrode 2b. In the second electrode 2b, each electrode is further extended in a direction of a space portion in which other thermoelectric element layers do not occupy, and is thermally connected to a member 5 including the high thermal conductive material. Note that, from the perspective of heat dissipation, an electrode having the same specifications as that of the second electrode 2b is further used as an electrodes 2b″ and disposed on the second substrate 2a.

Examples of the high thermal conductive material used for the member 5 include ceramic materials such as aluminum nitride, silicon nitride, and alumina having high insulating properties and high thermal conductivity.

Dimensions of the member 5 are not particularly limited as long as heat dissipation is maintained.

According to the second embodiment, for example, when the object to be cooled is disposed on a heat absorption surface which is the first substrate 1a side having the first electrode 1b, heat from the object to be cooled is absorbed from the heat absorption surface which is the first substrate 1a side, dissipated from the second substrate 2a side having the second electrode 2b and the electrode 2b″, and accumulated in the member 5 and dissipated therefrom. The area of the second electrode 2b (further including the electrode 2b″) is larger than the area of the first electrode 1b, and, due to further inclusion of the member 5, heat is dissipated more efficiently, rapidly and sufficiently than in the first embodiment. The thermoelectric conversion module having such a configuration enables more efficient dissipation of the heat generated from the object to be cooled.

### Third Embodiment

In the configuration of the thermoelectric conversion module of the present invention, the second substrate preferably has a through-hole, and the second electrode is preferably formed on both sides of the second substrate through the through-hole and electrically and thermally connected.

In addition, preferably, the other electrode surface side of the second electrode, which is opposite to one electrode surface side on the P-type thermoelectric element layer and N-type thermoelectric element layer side, extends on the second substrate on the opposite side of the second substrate from the P-type thermoelectric element layer and N-type thermoelectric element layer side and is disposed as a continuous layer.

Furthermore, the one electrode surface side of the second electrode on the P-type thermoelectric element layer and N-type thermoelectric element layer side may extend on the second substrate through an opening end of the through-hole, and may be disposed as a continuous layer.

FIG. 4 is a cross-sectional view illustrating a configuration of a thermoelectric conversion module according to a third embodiment of the present invention.

The thermoelectric conversion module according to the third embodiment of the present invention includes: a first substrate 11a having a first electrode 11b; a P-type thermoelectric element layer 13 and an N-type thermoelectric element layer 14; a second electrode 12b disposed opposite the first electrode 11b; and a second substrate 12a. Here, the second electrodes 12b are formed on both sides of the second substrate 12a through a through-hole 17, and electrically and thermally connected.

One electrode surface side of the second electrode 12b on the P-type thermoelectric element layer 13 and the N-type thermoelectric element layer 14 side and the other opposite electrode surface side of the second electrode 12b extend on the second substrate 12a and are disposed as a continuous layer.

For the second electrode 12b with a continuous layer provided on the second substrate 12a, the area can be further expanded.

The second electrode 12b is preferably adjusted as appropriate (not illustrated), in a range where electrical connection and thermal connection to the thermoelectric element layers are not impaired, and in a range where the ratio R is satisfied.

In the thermoelectric conversion module according to the third embodiment of the present invention, an object to be cooled 16 is thermally connected to the first substrate 11a side, for example.

The through-hole 17 can be formed by a known method. For example, it can be formed by drilling or plating. The through-hole 17 may be filled with a metal material or the like. The through-hole is filled, and thus heat exhaust efficiency is improved.

According to the third embodiment, the electronic element as the object to be cooled 16 is disposed on the first substrate 11a side having the first electrode 11b as the heat absorption surface, and thus the heat from the electronic element is absorbed from the heat absorption surface which is the first substrate 11a side, and dissipated from the second electrode 12b. The second electrode 12b extends through the through-hole 17 of the second substrate 12a and is disposed as a continuous layer on a back surface side with its surface expanded, heat is dissipated efficiently, rapidly and sufficiently. The thermoelectric conversion module having such a configuration enables more efficient dissipation of the heat generated from the electronic element as the object to be cooled 16.

### Fourth Embodiment

In the configuration of the thermoelectric conversion module of the present invention, preferably, the thermoelectric conversion module is disposed inside the through-hole of the second substrate, and the second electrode of the thermoelectric conversion module extends on the second substrate and is disposed as a continuous layer.

FIG. 5 is a cross-sectional view illustrating a configuration of a thermoelectric conversion module according to a fourth embodiment of the present invention.

The thermoelectric conversion module according to the fourth embodiment of the present invention includes: a first electrode 11b; a P-type thermoelectric element layer 13 and an N-type thermoelectric element layer 14; and a second electrode 12b disposed opposite the first electrode 11b. Here, the P-type thermoelectric element layer 13 and the N-type thermoelectric element layer 14 are disposed inside the second substrate 12a, and the second electrode 12b extends to a back surface side of the second substrate 12a and is disposed as a continuous layer.

The second electrode 12b is preferably adjusted as appropriate (not illustrated), in a range where electrical connection and thermal connection to the thermoelectric element layers are not impaired, and in a range where the ratio R is satisfied.

In the thermoelectric conversion module according to the fourth embodiment of the present invention, an object to be cooled 16 is thermally connected to the first electrode 11b, for example.

According to the fourth embodiment, the electronic element as the object to be cooled 16 is disposed on the first electrode 11b side as the heat absorption surface, and thus the heat from the electronic element is absorbed from the heat absorption surface which is the first electrode 11b side that is flush with the second substrate 12a, and dissipated from the second electrode 12b. The second electrode 12b extends and is disposed as a continuous layer on a back surface side of the second substrate 12a, and thus heat can be dissipated efficiently, rapidly and sufficiently. The thermoelectric conversion module having such a configuration enables more efficient dissipation of the heat generated from the electronic element as the object to be cooled 16.

### Thermoelectric Element Layer

The P-type thermoelectric element layer and the N-type thermoelectric element layer used in the present invention are not particularly limited, but are preferably formed of thermoelectric semiconductor materials, heat resistant resins, and thermoelectric semiconductor compositions containing an ionic liquid and/or inorganic ionic compound.

### Thermoelectric Semiconductor Material

The thermoelectric semiconductor material used in the thermoelectric element layer is preferably pulverized to a predetermined size by a micropulverizer or the like and used as thermoelectric semiconductor particles (hereinafter, the thermoelectric semiconductor material may be referred to as “thermoelectric semiconductor particles”).

A particle size of the thermoelectric semiconductor particles is preferably from 10 nm to 100 μm, more preferably from 20 nm to 50 μm, and even more preferably from 30 nm to 30 μm.

An average particle size of thermoelectric semiconductor fine particles was obtained by measurement using a laser diffraction particle size analyzer (Mastersizer 3000 available from Malvern Panalytical Ltd.), and used as the median of the particle size distribution.

The thermoelectric semiconductor material constituting the P-type thermoelectric element layer and the N-type thermoelectric element layer in the thermoelectric element layers used in the present invention is not particularly limited as long as the thermoelectric semiconductor material is a raw material that can generate thermoelectromotive force by providing a temperature difference. For example, bismuth-tellurium-based thermoelectric semiconductor materials such as P-type bismuth telluride and N-type bismuth telluride; telluride-based thermoelectric semiconductor materials such as GeTe and PbTe; antimony-tellurium-based thermoelectric semiconductor materials; zinc-antimony-based thermoelectric semiconductor materials such as ZnSb, Zn₃Sb₂, and Zn₄Sb₃; silicon-germanium-based thermoelectric semiconductor materials such as SiGe; bismuth selenide-based thermoelectric semiconductor materials such as Bi₂Se₃; silicide-based thermoelectric semiconductor materials such as β-FeSi₂, CrSi₂, MnSi_{1.73}, Mg₂Si; oxide-based thermoelectric semiconductor materials; Heusler materials such as FeVAl, FeVAlSi, and FeVTiAl; and sulfide-based thermoelectric semiconductor materials such as TiS₂ are used.

Among these materials, the thermoelectric semiconductor material used in the present invention is preferably a bismuth-tellurium-based thermoelectric semiconductor materials such as P-type bismuth telluride or N-type bismuth telluride.

The P-type bismuth telluride is preferably one for which the carrier is a positive hole and the Seebeck coefficient is a positive value, and for example, a P-type bismuth telluride represented by BixTe₃Sb_{2-X} is preferably used. In this case, X is preferably 0<X≤0.8, and more preferably 0.4≤X≤0.6. X of greater than 0 and 0.8 or less is preferred because the Seebeck coefficient and electrical conductivity become large, and characteristics as the P-type thermoelectric conversion material are maintained.

In addition, the N-type bismuth telluride is preferably one for which the carrier is an electron and the Seebeck coefficient is a negative value, and, for example, an N-type bismuth telluride represented by Bi₂Te_{3-Y}Se_{Y} is preferably used. In this case, Y is preferably 0≤Y≤3 (when Y=0, Bi₂Te₃), and more preferably 0.1≤Y≤2.7. Y of 0 or greater and 3 or less is preferred because the Seebeck coefficient and electrical conductivity become large, and characteristics as the N-type thermoelectric conversion material are maintained.

The blended amount of the thermoelectric semiconductor particles in the thermoelectric semiconductor composition is preferably from 30 to 99 mass %. The compounded amount thereof is more preferably from 50 to 96 mass %, and even more preferably from 70 to 95 mass %. If the compounded amount of the thermoelectric semiconductor particles is within the range described above, the Seebeck coefficient (absolute value of the Peltier coefficient) is large, a decrease in electrical conductivity is suppressed, and only thermal conductivity is reduced, and therefore a film exhibiting high thermoelectric performance and having sufficient film strength and flexibility is obtained. Thus, the compounded amount of the thermoelectric semiconductor particles is preferably within the range described above.

Furthermore, the thermoelectric semiconductor particles are preferably subjected to an annealing treatment (hereinafter, also referred to as an “annealing treatment A”). When the thermoelectric semiconductor particles are subjected to the annealing treatment A, the crystallinity of the thermoelectric semiconductor particles is improved, and a surface oxide film of the thermoelectric semiconductor particles is removed, and therefore the Seebeck coefficient (absolute value of the Peltier coefficient) of the thermoelectric conversion material increases, and the thermoelectric performance index can be further improved.

### Heat Resistant Resin

The heat resistant resin used in the present invention serves as a binder between the thermoelectric semiconductor particles, and is to increase flexibility of the thermoelectric element layer. The heat resistant resin is not particularly limited; however, a heat resistant resin that maintains various physical properties as a resin such as mechanical strength and thermal conductivity without impairing them when thermoelectric semiconductor particles undergo crystal growth by subjecting a thin film including the thermoelectric semiconductor composition to, for example, annealing is used.

Examples of the heat resistant resin include polyamide resins, polyamide-imide resins, polyimide resins, polyetherimide reins, polybenzoxazole resins, polybenzimidazole resins, epoxy resins, and copolymers having chemical structures of these resins. The heat resistant resin may be used alone, or a combination of two or more types of the heat resistant resins may be used. Among these resins, from the perspective of further increasing heat resistance and not adversely affecting crystal growth of the thermoelectric semiconductor particles in the thin film, the heat-resistant resin is preferably a polyamide resin, a polyamide-imide resin, a polyimide resin, or an epoxy resin, and from the perspective of excelling in flexibility, the heat-resistant resin is more preferably a polyamide resin, a polyamide-imide resin, or a polyimide resin. When a polyimide film is used as the support described above, the heat resistant resin is more preferably a polyimide resin from perspectives such as adherence with the polyimide film. Note that in the present invention, the term polyimide resin is used as a general term for polyimides and precursors thereof.

The heat-resistant resin preferably has a decomposition temperature of 300° C. or higher. If the decomposition temperature is within the range described above, the flexibility of the thermoelectric element layer can be maintained without loss of function as a binder even when the thin film including the thermoelectric semiconductor composition is annealed as described below.

The blended amount of the heat resistant resin in the thermoelectric semiconductor composition is preferably from 0.1 to 40 mass %, more preferably from 0.5 to 20 mass %, and even more preferably from 1 to 20 mass %. When the blended amount of the heat resistant resin is within the range described above, a film in which high thermoelectric performance and film strength are both achieved is obtained.

### Ionic Liquid

The ionic liquid that may be contained in the thermoelectric semiconductor composition is a molten salt obtained by combining a cation and an anion and means a salt that can be present as a liquid in any temperature region in −50° C. or higher and lower than 400° C. In other words, the ionic liquid is an ionic compound having a melting point in the range of −50° C. or higher and lower than 400° C. The melting point of the ionic liquid is preferably −25° C. or higher and 200° C. or lower, and more preferably 0° C. or higher and 150° C. or lower. Because the ionic liquid has characteristics such as having a significantly low vapor pressure and being nonvolatile, having excellent thermal stability and electrochemical stability, having a low viscosity, and having a high ionic conductivity, the ionic liquid can effectively suppress reduction of the electrical conductivity between the thermoelectric semiconductor materials as a conductivity aid. Furthermore, because the ionic liquid exhibits high polarity based on the aprotic ionic structure and excellent compatibility with the heat resistant resin is achieved, the electrical conductivity of the thermoelectric conversion material can be made uniform.

As the ionic liquid, a known or commercially available ionic liquid can be used. Examples thereof include those formed from nitrogen-containing cyclic cation compounds and derivatives thereof, such as pyridinium, pyrimidinium, pyrazolium, pyrrolidinium, piperidinium, and imidazolium; tetraalkylammonium-based amine cations and derivatives thereof, phosphine cations and derivatives thereof, such as phosphonium, trialkylsulfonium, and tetraalkylphosphonium; cation components, such as lithium cation and derivatives thereof, and anion components, such as Cl⁻, Br⁻, I⁻, AlCl₄⁻, Al₂Cl₇⁻, BF₄⁻, PF₆⁻, ClO₄⁻, NO₃⁻, CH₃COO⁻, CF₃COO⁻, CH₃SO₃⁻, CF₃SO₃⁻, (FSO₂)₂N⁻, (CF₃SO₂)₂N⁻, (CF₃SO₂)₃C⁻, AsF₆⁻, SbF₆⁻, NbF₆⁻, TaF₆⁻, F(HF)ₙ⁻, (CN)₂N, C₄F₉SO₃⁻, (C₂F₅SO₂)₂N⁻, C₃F₇COO⁻, and (CF₃SO₂)(CF₃CO)N⁻.

In the ionic liquid described above, from the perspective of high temperature stability, compatibility between the thermoelectric semiconductor material and the resin, suppression of reduction of the electrical conductivity between the thermoelectric semiconductor materials, and the like, the cation component of the ionic liquid preferably contains at least one type selected from the group consisting of pyridinium cations and derivatives thereof and imidazolium cations and derivatives thereof.

In ionic liquids containing pyridinium cations and derivatives thereof, the cation component is preferably 1-butyl-4-methylpyridinium bromide, 1-butylpyridinium bromide, or 1-butyl-4-methylpyridinium hexafluorophosphate.

In ionic liquids containing imidazolium cations and derivatives thereof, the cation component is preferably [1-butyl-3-(2-hydroxyethyl)imidazolium bromide] or [1-butyl-3-(2-hydroxyethyl)imidazolium tetrafluoroborate].

Furthermore, the ionic liquid described above preferably has a decomposition temperature of 300° C. or higher. When the decomposition temperature is in the range described above, as described below, even in a case where a thin film formed from the thermoelectric semiconductor composition is subjected to annealing, effect as the conductivity aid can be maintained.

The blended amount of the ionic liquid in the thermoelectric semiconductor composition is preferably from 0.01 to 50 mass %, more preferably from 0.5 to 30 mass %, and even more preferably from 1.0 to 20 mass %. When the blended amount of the ionic liquid is in the range described above, reduction of the electrical conductivity is effectively suppressed, and a film having a high thermoelectric performance can be obtained.

### Inorganic Ionic Compound

The inorganic ionic compound that may be contained in the thermoelectric semiconductor composition is a compound formed from at least a cation and an anion. Because the inorganic ionic compound is present as a solid in a wide range of temperature region, which is from 400 to 900° C., and has characteristics such as high ionic conductivity, the inorganic ionic compound can suppress reduction of the electrical conductivity between the thermoelectric semiconductor materials as a conductivity aid.

The blended amount of the inorganic ionic compound in the thermoelectric semiconductor composition is preferably from 0.01 to 50 mass %, more preferably from 0.5 to 30 mass %, and even more preferably from 1.0 to 10 mass %. When the blended amount of the inorganic ionic compound is in the range described above, reduction of the electrical conductivity is effectively suppressed and, as a result, a film having an enhanced thermoelectric performance can be obtained.

Note that, in a case where the inorganic ionic compound and the ionic liquid are used in combination, the total content of the inorganic ionic compound and the ionic liquid in the thermoelectric semiconductor composition is preferably from 0.01 to 50 mass %, more preferably from 0.5 to 30 mass %, and even more preferably from 1.0 to 10 mass %.

The thermoelectric element layer including the thermoelectric semiconductor composition can be formed, for example, by applying the thermoelectric semiconductor composition onto a substrate and drying the composition. By forming in this manner, numerous thermoelectric conversion element layers can be easily obtained at a low cost.

The method of applying the thermoelectric semiconductor composition onto the substrate to obtain a thermoelectric element layer is not particularly limited, and examples thereof include known methods such as screen printing, flexographic printing, gravure printing, spin coating, dip coating, die coating, spray coating, bar coating, and doctor blade coating. When the coating is to be formed in a pattern, a method such as screen printing or slot die coating by which the pattern can be easily formed using a screen plate having the desired pattern is preferably used.

The resulting coating film is then dried to form a thermoelectric element layer.

A thickness of the thermoelectric element layer is not particularly limited, but, from the perspective of thermoelectric performance and film strength, is preferably from 100 nm to 1000 μm, more preferably from 300 nm to 600 μm, and even more preferably from 5 to 400 μm.

The P-type thermoelectric element layer and the N-type thermoelectric element layer as thin films including the thermoelectric semiconductor composition are preferably further subjected to an annealing treatment (hereinafter, sometimes referred to as “annealing treatment B”). By subjecting the chip to the annealing treatment B, the thermoelectric performance can be stabilized, crystal growth of the thermoelectric semiconductor particles in the thin film can be promoted, and the thermoelectric performance can be further improved. The annealing treatment B is not particularly limited, but is ordinarily implemented in an atmosphere with the gas flow rate controlled, including in an inert gas atmosphere such as nitrogen or argon or in a reducing gas atmosphere, or is implemented under vacuum conditions, and while dependent on factors such as the heat resistance temperatures of the resin and ionic compound that are used, the annealing treatment B is typically implemented at a temperature of from 100 to 500° C. for several minutes to several tens of hours.

### Substrate

The first substrate and the second substrate used in the thermoelectric conversion module of the present invention are not particularly limited, and, each independently, can be a paper phenol substrate, a paper epoxy substrate, a glass composite substrate, a glass epoxy substrate, a glass polyimide substrate, a fluorine substrate, a glass PPO substrate, a glass, a ceramic, or a plastic film. Among these, a plastic film is preferable from the perspective of having flexibility and having a degree of freedom with respect to installation on a surface of a heat source. Furthermore, from the perspective of high heat resistance and less outgas generation, a polyimide film, a polyamide film, a polyether imide film, a polyaramid film, a polyamide-imide film, a polysulfone film, a glass composite substrate, a glass epoxy substrate, and a glass polyimide substrate are preferred. Further, from the perspective of high versatility, a polyimide film, a paper phenol substrate, a paper epoxy substrate, a glass composite substrate, a glass epoxy substrate, and a glass polyimide substrate are particularly preferred.

The thicknesses of the first substrate and the second substrate are each independently preferably from 1 to 1000 μm, more preferably from 10 to 500 μm, and even more preferably from 20 to 100 μm, from the perspectives of heat resistance and flexibility.

### Electrode

In the thermoelectric conversion module of the present invention, the metal materials used in the first electrode and the second electrode are not particularly limited, but, preferably, are each independently copper, gold, nickel, aluminum, rhodium, platinum, chromium, palladium, stainless steel, molybdenum, or an alloy containing any of these metals. In addition, a single layer may be used, but also a plurality of layers may be combined to form a multilayer configuration.

The thicknesses of the layers of the first electrode and the second electrode are each independently preferably from 10 nm to 200 μm, more preferably from 30 nm to 150 μm, and even more preferably from 50 nm to 120 μm. When the thicknesses of the layers of the first and second electrodes are within the range described above, electrical conductivity is high, resistance is low, and sufficient strength of the electrodes is obtained.

The first electrode and the second electrode are formed using the metal material described above. A method for forming the first and second electrodes is, for example, a method in which an electrode having no pattern formed thereon is provided on a substrate, and processed into a predetermined pattern shape by a known physical treatment or chemical treatment mainly using a photolithography method or a combination thereof, or a method in which a pattern of an electrode is directly formed by screen printing, an inkjet method, or the like.

Examples of methods for forming an electrode having no pattern formed thereon include dry processes including physical vapor deposition (PVD) methods, such as vacuum vapor deposition, sputtering, and ion plating or chemical vapor deposition (CVD) methods, such as thermal CVD and atomic layer deposition (ALD); or wet processes including various coating methods, such as dip coating, spin coating, spray coating, gravure coating, die coating, and doctor blade coating, and electrodeposition methods; silver salt methods; electrolytic plating; electroless plating; and lamination of metal foils. The method is appropriately selected according to the material for the electrode.

From the perspective of thermoelectric performance, the electrodes are required to exhibit high electrical conductivity and high thermal conductivity, and therefore electrodes that have been film-formed by plating or a vacuum film formation method are preferably used.

A bonding agent is used for joining between the P-type thermoelectric element layer and the N-type thermoelectric element layer and the electrodes.

Examples of the bonding agent include an electrically conductive paste. Examples of the electrically conductive paste include copper paste, silver paste, and nickel paste. When a binder is used, examples thereof include an epoxy resin, an acrylic resin, and a urethane resin.

Examples of methods for applying the bonding agent onto the electrodes on the substrate include known methods such as screen printing and dispensing methods.

Also, a solder material can be used for joining with the electrodes. The solder material may be appropriately selected, and examples thereof include known materials such as Sn, Sn/Pb alloys, Sn/Ag alloys, Sn/Cu alloys, Sn/Sb alloys, Sn/In alloys, Sn/Zn alloys, Sn/In/Bi alloys, Sn/In/Bi/Zn alloys, and Sn/Bi/Pb/Cd alloys.

Examples of methods for applying the solder material onto the electrodes on the substrate include known methods such as screen printing and dispensing methods.

Although embodiments of the thermoelectric conversion module of the present invention have been described above, the present invention is not limited to the embodiments described above, and various modifications can be made.

According to the thermoelectric conversion module of the present invention, a thermoelectric conversion module in which heat dissipation is further improved by a simple configuration of making the area of the second electrode larger than the area of the first electrode is obtained.

### INDUSTRIAL APPLICABILITY

According to the thermoelectric conversion module of the present invention, a thermoelectric conversion module which is composed of 7-type thermoelectric conversion element and in which heat dissipation is further improved by a simple configuration of making the area of the second electrode larger than the area of the first electrode is obtained.

Therefore, it is considered that the thermoelectric conversion module is applied mainly to cooling uses in the field of electronic devices described above. Also, it can be applied to power generation uses in which exhaust heat from factories and various combustion furnaces such as waste combustion furnaces and cement combustion furnaces, exhaust heat from automobile combustion gas, and exhaust heat from electronic equipment are converted into electricity, and, further, power generation uses utilizing a temperature difference between human body temperature and outside air, for example, when it is worn on the neck or arm.

### REFERENCE SIGNS LIST

1a: First substrate
1b: Second electrode
2a: Second substrate
2b, 2b′: Second electrode
2b″: Electrode
3: P-type thermoelectric element layer
4: N-type thermoelectric element layer
5: Member
11a: First substrate
11b: First electrode
12b, 12b′: Second electrode
13: P-type thermoelectric element layer
13: N-type thermoelectric element layer
15: Heat dissipation substrate
16: Object to be cooled
17: Through-hole

1: A thermoelectric conversion module including a first electrode, a P-type thermoelectric element layer and an N-type thermoelectric element layer, and a second electrode disposed opposite the first electrode,
the thermoelectric conversion module comprising a plurality of PN-junction pairs in which the P-type thermoelectric element layer and the N-type thermoelectric element layer are PN-joined through the first electrode or the second electrode, the plurality of PN-junction pairs being electrically connected in series alternately by the first electrode and the second electrode,
wherein an area of the second electrode is larger than an area of the first electrode.

2: The thermoelectric conversion module according to claim 1, wherein a ratio R of the area of the second electrode to the area of the first electrode is 1.20 or greater.

3: The thermoelectric conversion module according to claim 1, further comprising a first substrate and/or a second substrate.

4: The thermoelectric conversion module according to claim 1, wherein an extending portion of the second electrode is thermally connected to a member comprising a high thermal conductive material.

5: The thermoelectric conversion module according to claim 3, wherein the second substrate has a through-hole, and the second electrode is formed on both sides of the second substrate through the through-hole; and an other electrode surface side of the second electrode, which is opposite to one electrode surface side on the P-type thermoelectric element layer and N-type thermoelectric element layer side, extends on the second substrate on the opposite side of the second substrate from the P-type thermoelectric element layer and N-type thermoelectric element layer side and is disposed as a continuous layer.

6: The thermoelectric conversion module according to claim 5, wherein the thermoelectric conversion module is disposed inside the through-hole of the second substrate, and the second electrode of the thermoelectric conversion module extends on the second substrate through the through-hole and is disposed as a continuous layer.
